(19) United States
(12) Patent Application Publication
(10) Pub. No.: US 2008/0116519 A1
(43) Pub. Date: May 22, 2008

(54) Integrated Circuit Used in Smart Power Technology

(76) Inventor: Wolfgang Wilkening, Pfullingen (DE)

Correspondence Address: KENYON & KENYON LLP, ONE BROADWAY, NEW YORK, NY, 10004, US

(21) Appl. No.: 11/665,570

(22) PCT Filed: Aug. 16, 2005
(86) PCT No.: PCT/EP05/54023

§ 371 Date: Oct. 2, 2007

(30) Foreign Application Priority Data
Oct. 16, 2004 (DE) 10 2004 050 767.8

(51) Int. Cl. H01L 27/06

(52) U.S. Cl. 257/360; 257/E27.016

(57) ABSTRACT

An integrated circuit used in smart power technology, in particular, for use in automobile applications, which includes: high-voltage terminals for connection to a high voltage, a smart circuit device having low-voltage components, and an ESD protective circuit, connected between the high-voltage terminals, which has a MOSFET whose source and drain are connected to the high-voltage terminals, and whose gate is connected to its source via a resistor, the gate resistor being made of polycrystalline silicon. High ESD resistance with relatively low surface area usage and accordingly low costs may be achieved by using the polyresistor as the gate resistor. One protective diode, which blocks above the supply voltage, may be connected in the blocking direction between source and gate and between gate and drain of the MOSFET.

### FIELD OF THE INVENTION

The present invention relates to an integrated circuit used in smart power technology.

### BACKGROUND INFORMATION

Smart power circuits of this type contain drivers or an output stage in which currents of a few amperes are switched and so-called smart circuit parts which are designed for currents of a few microamperes to milliamperes. They are used, in particular, in automobile applications in a voltage range of 40 V to 60 V.

In smart power technology, the components of the smart circuit parts are insulated against the substrate via pn-junctions or np-junctions having high breakdown voltages. In n-channel MOSFETs, a deep-lying n-trough, for example, a deep n-well or n-epitaxial layer, may be implemented on a p-substrate underneath a p-trough used as a body terminal, the n-trough insulating the terminal of the low-voltage n-channel transistors against the substrate. The breakdown voltage of the deep-lying n-trough relative to the substrate is greater than 15 V, for example, in the range of 40 V to 80 V.

Special protective structures, i.e., ESD protective circuit devices, are used for protection against electrostatic discharges (ESD). They have an HVMOS transistor, for example, DMOS, which has a voltage resistance of 20 V to 80 V, for example. Drain and source are located between the terminal pads, between which the ESD current flows. The gate is connected to the source via a gate resistor. Under ESD load, the gate is raised via the parasitic drain-gate capacitance of the MOSFET, so that the MOSFET dissipates the ESD current via the open MOS channel. Since the transistor is dimensioned to be sufficiently large, the occurring ESD voltage is limited, so that no damage occurs to the drivers or the output stage or the smart power circuit parts, i.e., the low-voltage circuit parts. In normal operation, the gate is pulled to ground potential by the gate resistance, so that the transistor is switched to the non-conducting state. Since the gate resistance is dimensioned to be sufficiently large, the gate voltage injected via the parasitic drain-gate capacitance may be held for a sufficiently long time. The gate resistance is thus typically 5 kOhm to 100 kOhm.

In smart power technology, diffused regions are formed for the gate resistance, for example, pwell, pbody, pfield resistances. Resistances of this type may be provided in the above-specified values via diffusion with a relatively small surface area occupancy and thus at low cost.

A disadvantage of such protective transistor circuits, however, is that raising the gate is problematic. Together with the p-substrate, the diffused gate resistors form parasitic transistors. The first parasitic substrate transistor is the vertical parasitic pnp-transistor, which is formed via p-diffusion, for example, pbody as the emitter, n-trough, for example, n-epitaxial layer, and p-substrate. The second parasitic transistor is the lateral npn-transistor, which may act between an n-trough of another component or component block, for example, a digital trough as the emitter, p-substrate as the base, and the n-trough of the diffused resistor as the collector.

### SUMMARY

The integrated circuit according to example embodiments of the present invention may provide certain advantages over the related art. According to example embodiments of the present invention, the gate resistor is arranged as a polyresistor, i.e., is made of polycrystalline silicon. This takes into account that basically a larger surface area is needed initially than in the case of conventional diffused resistors. It is recognized, however, that the above-mentioned disadvantages of the parasitic transistors of diffused resistors do not occur due to the use of polyresistors. The ESD resistance may thus be increased up to twofold with the same surface area used, i.e., at the same costs. Alternatively, the chip surface area, i.e., the costs, may be reduced for a predefined ESD resistance.

According to example embodiments of the present invention, the switching properties may be considerably improved compared to conventional systems. A diode limiting control voltage UGS, for example, a Zener diode, may be connected between gate and source in the blocking direction. Furthermore, a diode blocking above the operating voltage, for example, a Zener diode, or a chain of diodes may be connected between gate and drain to additionally raise the gate also via this path.

Example embodiments of the present invention are described in more detail below with reference to the appended Figures.

### BRIEF DESCRIPTION OF THE DRAWINGS

FIG. 1 shows a circuit diagram of an integrated circuit according to an example embodiment of the present invention having an ESD protective transistor circuit.

FIG. 2 shows an ESD protective transistor circuit according to another embodiment.

FIG. 3 shows an ESD protective transistor circuit according to another embodiment.

### DETAILED DESCRIPTION

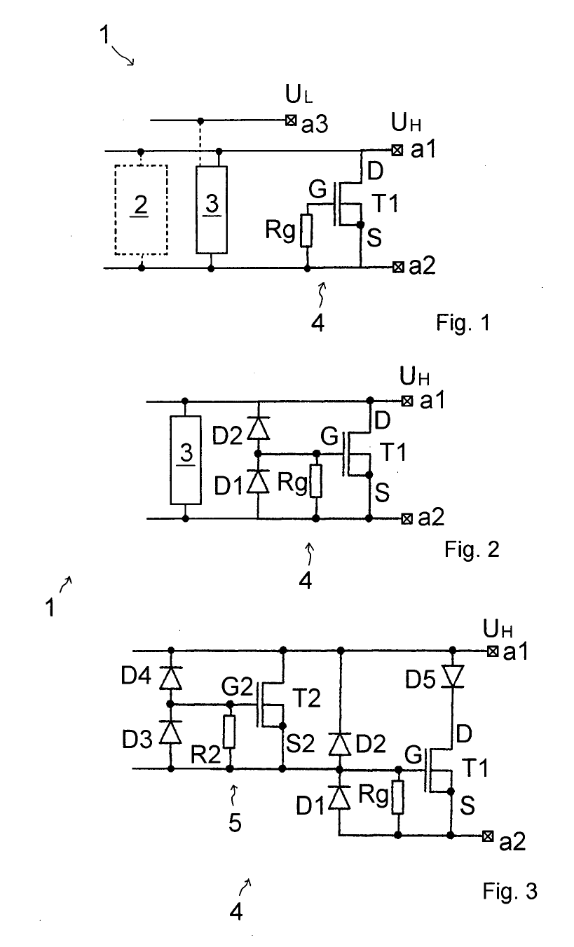

An integrated circuit 1 has, according to the example embodiment shown in FIG. 1, an output stage 2 or a driver device in which currents of a few amperes are switched, and a smart circuit device 3 having smart circuit elements which are provided for currents of a few microamperes to milliamperes. Output stage 2 and smart circuit device 3 are connected between a high-voltage terminal pad a1 for a high voltage UH>15 V and a ground terminal pad a2 and optionally other terminal pads. A further terminal pad a3 for a low voltage UL, for example, <5 V, and optionally another ground terminal pad may be provided. The low-voltage components of smart circuit device 3 may, however, be basically also connected to high voltage UH via appropriate series resistors. Output stage 2 may also be situated outside integrated circuit 1 and is therefore depicted in FIG. 1 in dotted lines and is not depicted in the other figures.

The components of smart circuit device 3 are insulated against the substrate of the chip via pn-junctions or np-junctions having high breakdown voltages. In low-voltage n-channel MOSFETs, a deep-lying n-trough, for example, a deep n-well or n-epitaxial layer, may be implemented on a p-substrate underneath a p-trough used as a body terminal, the n-trough insulating the terminal of the low-voltage n-channel transistors against the substrate. The breakdown voltage of the deep-lying n-trough relative to the substrate is greater than 15 V, for example, in the range of 40 V to 80 V.

An ESD protective transistor circuit device 4 is also provided which, as illustrated in FIG. 1, has an HVMOS transistor T1, for example, a DMOS transistor T1, which has a voltage resistance of 20 V to 80 V, for example. According to FIG. 1, drain D is connected to high-voltage terminal pad a1, and source S is connected to ground terminal pad a2.

Alternatively, in an appropriate integrated circuit, drain D may also be directly connected to an input pad or output pad whose voltage resistance exceeds 15 V. Gate G is connected to source S via a resistor Rg. Under ESD load, gate G is increased via the parasitic drain-gate capacitance of T1. T1 then dissipates the ESD current between drain D and source S via the open MOS channel. Since T1 is dimensioned to be sufficiently large, the voltage is thereby limited, so that no damage occurs. In normal operation, gate G of T1 is pulled to ground potential GND, i.e., 0 V, by gate resistance Rg, so that transistor T1 is blocked by gate-source voltage UGS=0. Rg is designed to have a sufficiently high resistance so that under ESD load the above-described capacitive increase of T1 is achieved. For this purpose, Rg is typically 5 kOhm to 100 kOhm.

High voltage UH may be a high supply voltage when, for example, output stage 2 drawn in dashed lines is connected to pads a1 and a2. Pad a1 may, however, also be used as a high-voltage input/output pad.

Rg is arranged as a polyresistor, i.e., is made of polycrystalline silicon. This prevents the effects of parasitic transistors described for conventional diffused p-resistors from occurring. The ESD resistance may thus be increased for the same surface area usage and accordingly the same costs.

As illustrated in FIG. 2, a diode D1, for example, a Zener diode, is connected between gate G and source S. D1 is to limit gate-source voltage UGS. Furthermore, a diode D2 blocking above operating voltage UH, in particular a Zener diode, or a chain of diodes may be connected between drain D and gate G to additionally raise gate G also over this path, i.e., pull the gate voltage upward in the event of an ESD pulse when the limit voltage of the diode switched in the blocking direction is exceeded.

FIG. 3 shows another example embodiment in which the gate of transistor T1 is more strongly raised via an appropriately connected prestage 5, which is provided according to circuit device 4 of FIG. 2. Prestage 5 has a second MOSFET T2, a resistor R2, connected between gate G2 and source S2 of second MOSFET T2, and diodes D3 and D4. Also in this case, R2 is arranged as a polyresistor.

In the example embodiments illustrated in FIGS. 1 through 3, a polarity reversal protection diode D5 may be connected between terminal pad a1 and drain D, which is shown as an example in FIG. 3.

Alternatively to the illustrated embodiment, transistors T2 and T2 may also be HVPMOS transistors in particular. In this case, the high voltage is connected to the source and ground to the drain.

1-10. (canceled)

11. An integrated circuit using smart power technology, comprising:
high-voltage terminals configured to connect to a high voltage;
a smart circuit device including low-voltage components;
an ESD protective circuit connected between the high-voltage terminals, including a MOSFET having a source and a drain connected to the high-voltage terminals and a gate connected to its source via a gate resistor made of polycrystalline silicon.

12. The integrated circuit according to claim 11, wherein the MOSFET is arranged an n-channel MOSFET for high-voltage applications.

13. The integrated circuit according to claim 11, wherein the MOSFET is arranged as one of (a) an HVPMOS transistor and (b) a DMOS transistor.

14. The integrated circuit according to claim 11, further comprising a protective diode connected between the source and the gate in a blocking direction.

15. The integrated circuit according to claim 11, further comprising a protective diode, configured to block above a supply voltage, connected between the gate and the drain in a blocking direction.

16. The integrated circuit according to claim 11, further comprising a prestage, having a second MOSFET and a resistor made of polycrystalline silicon connected between a gate and a source of the second MOSFET, connected between the gate and the drain of the MOSFET.

17. The integrated circuit according to claim 11, further comprising a polarity reversal protective diode connected between a high-voltage terminal and the MOSFET (T1).

18. The integrated circuit according to claim 11, further comprising an output stage for power currents between the high-voltage terminals.

19. The integrated circuit according to claim 11, wherein the low-voltage components of the smart circuit device are insulated against a substrate by semiconductor junctions having breakdown voltages at least one of (a) greater than 15 V and (b) in a range of 40 V to 80 V.

20. The integrated circuit according to claim 19, wherein the smart circuit device has low-voltage n-channel MOSFETs having a p-trough used as a body terminal on a deep-lying n-trough on a p-substrate, the breakdown voltage of the deep-lying n-trough against the p-substrate at least one of (a) greater than 15 V and (b) in a range of 40 V to 80 V.
